(19) United States
(12) Patent Application Publication
(10) Pub. No.: US 2014/0191327 A1
(43) Pub. Date: Jul. 10, 2014

(54) SEMICONDUCTOR MEMORY DEVICE

(71) Applicant: FUJITSU SEMICONDUCTOR LIMITED, Yokohama-shi (JP)

(72) Inventors: Tomoya TSURUTA, Koganei (JP); Ryo TANABE, Kawasaki (JP)

(73) Assignee: FUJITSU SEMICONDUCTOR LIMITED, Yokohama-shi (JP)

(21) Appl. No.: 14/132,967

(22) Filed: Dec. 18, 2013

(30) Foreign Application Priority Data
Jan. 10, 2013 (JP) 2013-002927

(51) Int. Cl. H01L 27/092; H01L 27/105

(52) U.S. Cl. CPC H01L 27/0928; H01L 27/1052
USPC 257/371

(57) ABSTRACT

A semiconductor memory device has a memory cell array with memory cells, each including first and second conduction type transistors, column-side peripheral circuits disposed with the same row-direction interval as the memory cells, a first conduction type well region formed within the memory cell array, a second conduction type well region formed within the first conduction type well region and is disposed separately in the row direction, a second conduction type well contact region disposed extending in the row direction among the memory cells, a first conduction type well contact region disposed extending in the column direction among the memory cells, a column-side peripheral contact region, a first conduction type back gate voltage line connecting to the first conduction type well region; and a second conduction type back gate voltage line connecting to the second conduction type well.

### CROSS-REFERENCE TO RELATED APPLICATION

This application is based upon and claims the benefit of priority of the prior Japanese Patent Application No. 2013-002927, filed on Jan. 10, 2013, the entire contents of which are incorporated herein by reference.

### FIELD

The present invention relates to a semiconductor memory device.

### BACKGROUND

Semiconductor memory devices store data in memory cells with various configurations, such as that of DRAM, SRAM, FeRAM, flash memory, and similar. Of these, static RAM (SRAM) memory cells have a pair of cross-connected CMOS inverters and NMOS transmission transistors. Further, SRAM has word driving circuits which respectively drive word lines provided at each row, column selection gates provided at each column, sense amplifiers, write amplifiers, and other peripheral circuits, and these are also formed from CMOS circuits.

In general, the semiconductor substrate of an LSI having CMOS circuits has N-type well regions to form PMOS transistors and P-type well regions to form NMOS transistors. For example, at the surface of a P-type semiconductor substrate, deep N-type well regions are formed, and P-type well regions are formed within the deep N-type well regions. Or, at the surface of an N-type semiconductor substrate, deep P-type well regions are formed, and N-type well regions are formed within the deep P-type well regions. The ground voltage is supplied as a back gate voltage to the P-type well regions, and the power supply voltage is supplied as a back gate voltage to the N-type well regions, so that the PN junctions between each of the well regions and the source regions and drain regions within the well regions are kept at a reverse-direction potential.

There are many cases in which the source terminal of an NMOS transistor is connected to ground voltage, and so due to this configuration it is advantageous to apply ground voltage to the P-type well regions in which NMOS transistors are formed. Similarly, there are many cases in which the source terminal of a PMOS transistor is connected to the power supply voltage, and so due to this configuration it is advantageous to apply the power supply voltage to the N-type well regions in which PMOS transistors are formed.

The semiconductor memory device is disclosed in Japanese Patent Application Laid-open No. H6-5081, Japanese Patent Application Laid-open No. 2007-305787 and Japanese Patent Application Laid-open No. 2009-194190

### SUMMARY

However, in recent years LSI microminiaturization techniques have shortened the channel lengths of MOS transistors, made gate insulating films thinner, lowered threshold voltages, and lowered power supply voltage potentials. Although microminiaturization techniques have raised integration levels and increased operation speeds, the occurrence of leakage currents of MOS transistors in the off state is viewed as a problem.

One method to suppress off-leakage currents of MOS transistors is to make the back gate voltage a potential different from the ground voltage and power supply voltage. That is, a P-type back gate voltage lower than the ground voltage is applied to the P-type well region in which an NMOS transistor is formed, or, an N-type back gate voltage higher than the power supply voltage is applied to the N-type well region in which a PMOS transistor is formed. By applying such a back gate voltage, the threshold voltages of NMOS transistors and PMOS transistors is each raised, and leakage currents in the off state is suppressed.

Hence two back gate voltage contact regions are to be disposed in a memory cell region and in the peripheral cell region.

One type of the embodiment is a semiconductor memory device, comprising:
a memory cell array in which are disposed a plurality of memory cells, each including a first conduction type transistor and a second conduction type transistor;
a plurality of column-side peripheral circuits which are disposed with the same row-direction interval as the memory cells, and which are disposed corresponding to a group of column-direction memory cells disposed in the column direction;
a first conduction type well region which is formed within the memory cell array, and in which are formed the second conduction type transistors of the plurality of memory cells;
a second conduction type well region which is formed within the first conduction type well region and is disposed separately in the row direction, and in which are formed the first conduction type transistors of the plurality of memory cells;
a second conduction type well contact region which is disposed extending in the row direction among the plurality of memory cells, and which is provided in the plurality of second conduction type well regions;
a first conduction type well contact region which is disposed extending in the column direction among the plurality of memory cells, and provided in the first conduction type well region;
a column-side peripheral contact region, which is disposed among the plurality of column-side peripheral circuits, and disposed at a position corresponding to the first conduction type well contact region, and moreover provided in the first conduction type well region and the second conduction type well regions;
a first conduction type back gate voltage line, which connects to the first conduction type well region within the first conduction type well contact region; and
a second conduction type back gate voltage line, which connects to the second conduction type well region within the second conduction type well contact region.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1 illustrates an example of memory cells and column-side peripheral circuits in a semiconductor memory device of an embodiment.

FIG. 2 illustrates a schematic configuration of the semiconductor substrate of the semiconductor memory device of this embodiment.

FIG. 3 and FIG. 4 illustrate layouts of transistors in a memory cell array and column-side peripheral circuits of a semiconductor device of this embodiment.

FIG. 5 illustrates the first example of back gate voltage wires within a memory macro.

FIG. 6 illustrates a second example of back gate voltage lines in a memory macro.

FIG. 7 illustrates back gate voltage lines in a memory macro of the embodiment.

FIG. 8 illustrates another type of back gate voltage lines in a memory macro in this embodiment.

FIG. 9 illustrates the configuration of dummy cells DC comprised by an N-type well contact region 11.

FIG. 10 illustrates the configuration of dummy cells DC comprised by the P-type well contact regions 10.

### DESCRIPTION OF EMBODIMENTS

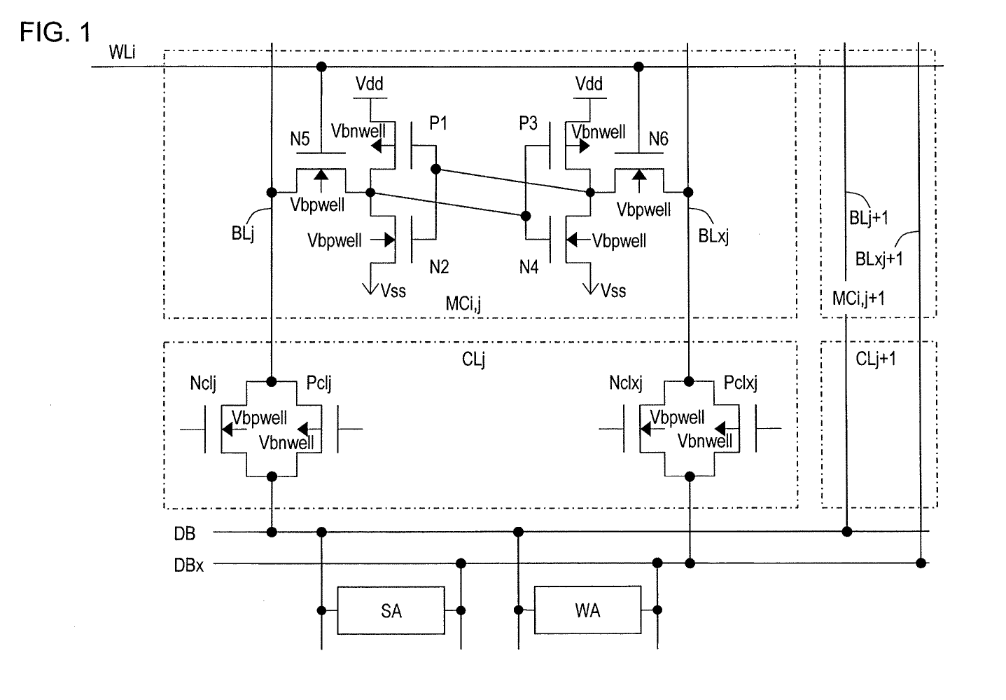

FIG. 1 illustrates an example of memory cells and column-side peripheral circuits in a semiconductor memory device of an embodiment. In FIG. 1, a word line WLi, bit lines BLj and KA, memory cells MCi,j and MCi,j+1, and column-side peripheral circuits CLj, CLj+1 corresponding thereto, of a portion of the semiconductor memory device are illustrated; in addition, a sense amplifier SA, write amplifier WA, and data buses DB, DBx are illustrated as peripheral circuits.

The memory cell MCi,j has an inverter with a PMOS transistor P1 and NMOS transistor N2 connected between the power supply voltage Vdd and ground Vss, and an inverter having a PMOS transistor P3 and NMOS transistor N4 connected between the power supply voltage Vdd and ground Vssw; the inputs and outputs of these inverters are cross-connected, and the pair of connection nodes are held at the H and L level potentials. The memory cell MCi,j has transmission transistors, comprising NMOS transistors N5 and N6, between the pair of connection nodes at which the inputs and outputs of the pair of inverters are cross-connected and the bit line pair BLj, BLxj, respectively. The gates of these NMOS transistors N5, N6 are connected to the word line WLi.

Further, column-side peripheral circuits CLj are provided between the bit lines BLj, BLxj and the data bus lines DB, DBx, respectively, and have NMOS and PMOS transistors Nclj, Pclj, Nclxj, Pclxj forming CMOS transfer gates. The column-side peripheral circuits CLj+1 have a similar circuit configuration. The data bus line pair DB, DBx provided in common with a plurality of bit line pairs are connected to the sense amplifier circuit SA and write amplifier circuit WA.

The memory array of the semiconductor memory device has for example memory cells MC disposed in an array of m rows and n columns, m rows of word lines WL, and n columns of bit line pairs BL, BLX. The number of memory cells, word lines, and bit line pairs of the memory array differ according to the data storage capacity of the semiconductor memory device.

In this way, the memory cell array with a plurality of memory cells and the column-side peripheral circuits have NMOS transistors of a first conduction type (N type) and PMOS transistors of a second conduction type (P type). Hence the semiconductor substrate on which the semiconductor memory device is formed has P-type well regions in which NMOS transistors are formed, and N-type well regions in which PMOS transistors are formed.

The N-type back gate voltage Vbnwell of the PMOS transistors in memory cells MC and column-side peripheral circuits and in row-side peripheral circuits, not illustrated, of this embodiment, is higher than the power supply voltage Vdd, or is dynamically controlled at the power supply voltage Vdd and a voltage higher than the power supply voltage Vdd.

However, the P-type back gate voltage Vbpwell of the NMOS transistors in memory cells MC and column-side peripheral circuits and in row-side peripheral circuits, not illustrated, of this embodiment, is a negative voltage lower than ground voltage Vss, or is dynamically controlled at ground voltage Vss and a voltage lower than ground voltage Vss.

Hence in the semiconductor memory device of this embodiment, a line for the N-type back gate voltage Vbnwell and a line for the P-type back gate voltage Vbpwell are provided on the semiconductor substrate separately from the line for the power supply voltage Vdd and the line for ground Vss.

By thus making the N-type back gate voltage Vbnewll a voltage higher than the power supply voltage Vdd, the threshold value of PMOS transistors is effectively raised, and leakage currents in the off state can be suppressed. Similarly, by making the P-type back gate voltage Vbpwell a voltage lower than ground voltage Vss, the threshold value of NMOS transistors is effectively raised, and leakage currents in the off state is suppressed.

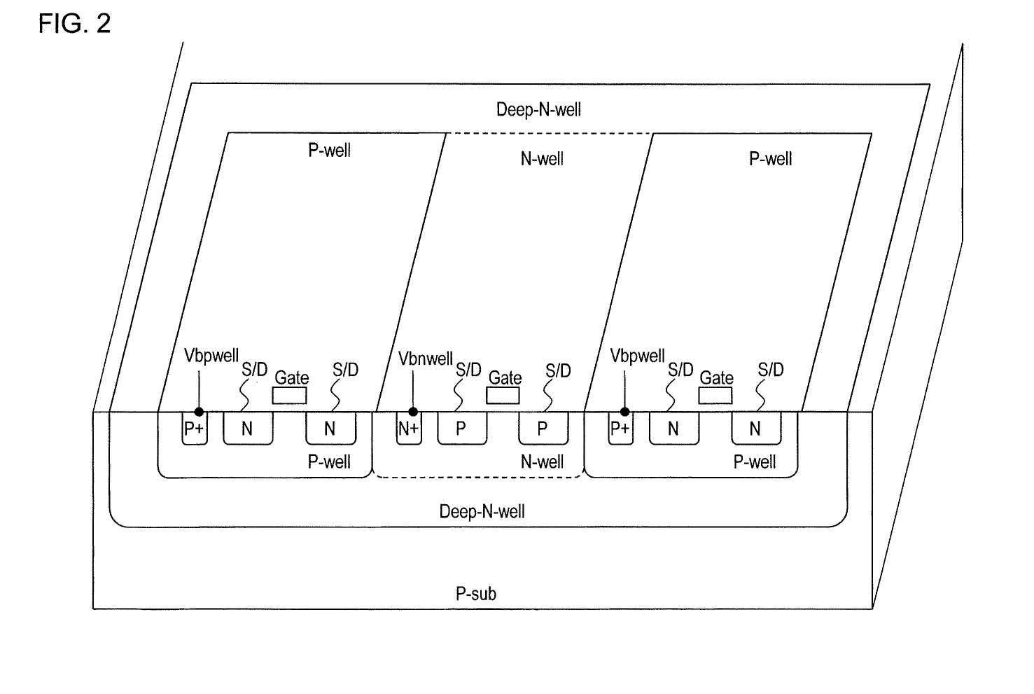

FIG. 2 illustrates a schematic configuration of the semiconductor substrate of the semiconductor memory device of this embodiment. In this example, a comparatively deep N-type well region Deep-N-well is formed in a P-type semiconductor substrate P-sub, and a plurality of shallower P-type well regions P-well are formed in the deep N-type well region Deep-N-well. N-type well regions N-well are located between the P-type well regions P-well.

The N-type well regions N-well are shallower than the deep N-type well region Deep-N-well; the shallow region of the deep N-type well region Deep-N-well may be used as the N-type well regions N-well without modification, or N-type impurities may be implanted in the shallow region in the deep N-type well region Deep-N-well to form the N-type well region N-well.

In the P-type well regions P-well, N-type source/drain regions S/D and P-type well contact regions P+ for application of the P-type back gate voltage Vbpwell are formed, and gate electrodes Gate are formed on the substrate between source/drain regions S/D with a gate oxide film, not illustrated, interposed. A line to supply the P-type back gate voltage Vbpwell is connected to the P-type well contact regions P+.

In the N-type well regions N-well, P-type source/drain regions S/D and N-type well contact regions N+ for application of the N-type back gate voltage Vbnwell are formed, and gate electrodes Gate are formed on the substrate between source/drain regions S/D with a gate oxide film, not illustrated, interposed. A line to supply the N-type back gate voltage Vbnwell is connected to the N-type well contact regions N+.

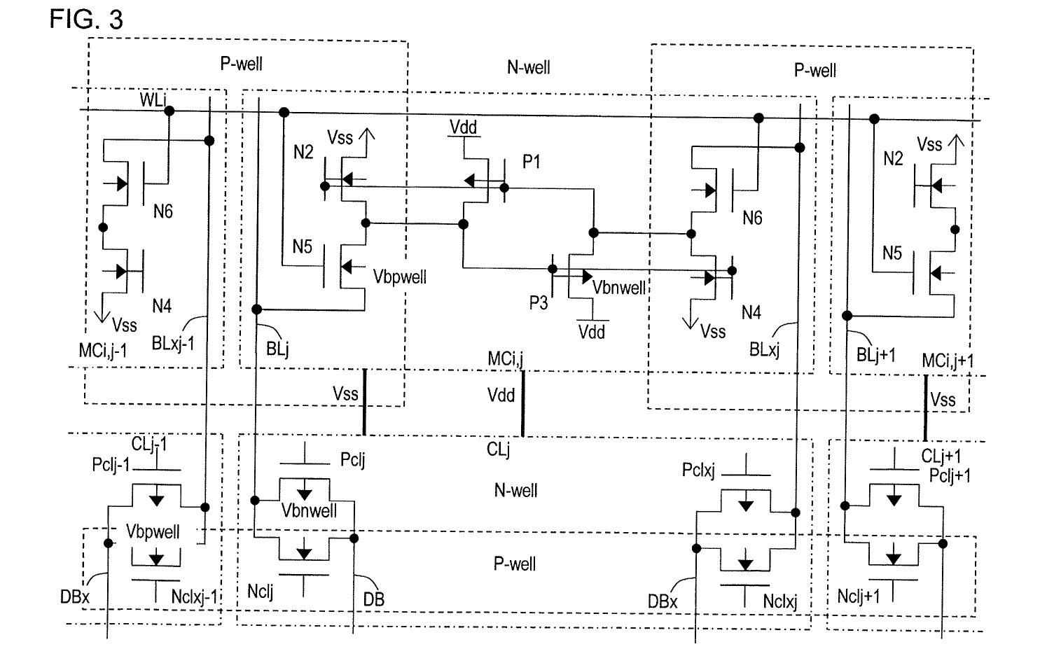

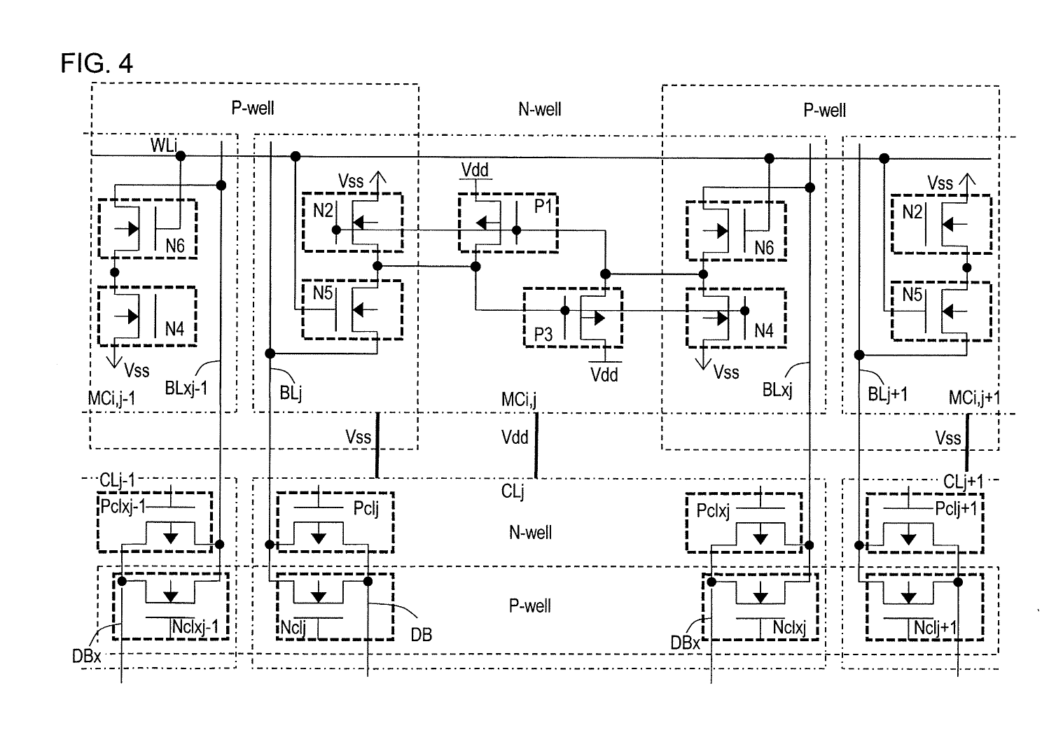

FIG. 3 and FIG. 4 illustrate layouts of transistors in a memory cell array and column-side peripheral circuits of a semiconductor device of this embodiment. FIG. 3 illustrates, instead of a specific layout, the disposition in P-type well regions P-well and N-type well regions N-well, indicating the positional relationship of NMOS transistors and PMOS transistors. FIG. 4 uses broken-line rectangles to indicate the regions of MOS transistors in the circuit diagram of FIG. 3. The circuit configuration is the same in FIG. 3 and FIG. 4.

As explained using FIG. 2, three P-type well regions P-well are disposed in the N-type well region N-well in the plane view of FIG. 3. The P-type well regions P-well on the left and right are isolated regions enclosed by N-type well regions in the memory cell array. The P-type well region P-well on the lower side is formed in the column-side peripheral circuits CL, and is an isolated region enclosed by N-type well regions. P-type well regions P-well are indicated by dashed lines.

FIG. 3 depicts three memory cells MCi,j−1, MCi,j, MCi,j+1, disposed in the row direction. The region of the three memory cells is indicated by dot-dash lines. FIG. 3 depicts three column selection circuits CLj−1, aj, CLj+1 as column-side peripheral circuits; the regions of these three column selection circuits are also indicated by dot-dash lines.

The two PMOS transistors P1, P3 in the memory cell MCi,j illustrated in FIG. 1 are disposed within an N-type well region N-well. Of the four NMOS transistors, two NMOS transistors N2, N5 are disposed in the left-side P-type well region P-well, and the remaining two NMOS transistors N4, N6 are disposed in the right-side P-type well region P-well. The two NMOS transistors N4, N6 in the memory cell MCi,j−1 adjacent on the left are disposed in the left-side P-type well region P-well, and the two NMOS transistors N2, N5 in the memory cell MCi,j+1 adjacent on the right are disposed in the right-side P-type well region P-well.

Thus as illustrated in FIG. 2, in a memory cell array, a plurality of P-type well regions P-well extending in the column direction are arranged in a strip shape in the row direction. The region of one memory cell MC comprises one-half of the regions of P-type well regions P-well on the left and right, and the region of the N-type well region N-well therebetween; four NMOS transistors and two PMOS transistors are disposed within the P-type well regions P-well and the N-type well region N-well.

The column selection circuit CLj which is a column-side peripheral circuit has a pair of CMOS transfer gates, as explained using FIG. 1. That is, a CMOS transfer gate having a PMOS transistor Pclj and an NMOS transistor Nclj connecting the bit line BLj to the data bus DB, and a CMOS transfer gate having a PMOS transistor Pclxj and an NMOS transistor Nclxj connecting the bit line BLxj to the data bus DBx, are provided.

And, as illustrated in FIG. 3, in the region of a column selection circuit, a P-type well region P-well extending in the row direction is provided within the N-type well-region N-well, and within the column selection circuit CLj, two PMOS transistors Pclj, Pclxj are disposed within the N-type well region N-well and two NMOS transistors Nclj, Nclxj are disposed within the P-type well region P-well.

Further, two bit lines BLj, BLxj, a ground line Vss, and a power supply line Vdd are provided, disposed in the column direction from the memory cell MCi,j to the column selection circuit CLj corresponding thereto. Although not illustrated, the ground line Vss and power supply line Vdd are disposed extending in the vertical direction, that is in the column direction, within the memory cell array. Hence four lines are formed between the memory cell array group disposed in the column direction and the column selection circuit CL corresponding thereto.

Although not illustrated in FIG. 3 and FIG. 4, a contact structure for the N-type back gate voltage Vbnwell is provided in the N-type well region N-well, and the N-type back gate voltage Vbnwell and N-type well region N-well are connected. Hence a line is provided for this N-type back gate voltage. Similarly, a contact structure for the P-type back gate voltage Vbpwell is provided within the P-type well region P-well, and the P-type back gate voltage Vbpwell and P-type well region P-well are connected. Hence a line is provided for this P-type back gate voltage.

### Examples of Back Gate Voltage Lines in a Memory Macro

Next, two examples of back gate voltage lines within a memory macro are explained. A characteristic of SRAM is high-speed access. And, a system LSI has internally a plurality of SRAM memory macros. However, the memory data capacity differs according to the functions of the circuits requiring the memory macros. A memory macro for which a large data capacity is used has numerous memory cells. Conversely, a memory macro for which a small data capacity suffices has a small number of memory cells.

It is desirable that the area of memory macros embedded within a system LSI be made as small as possible.

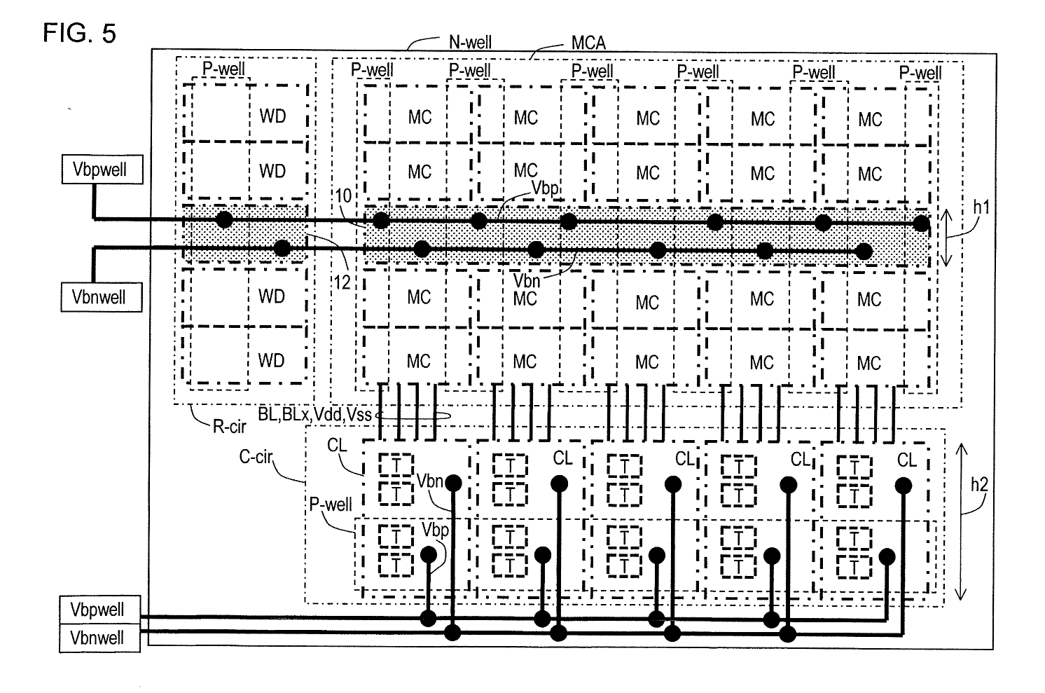

FIG. 5 illustrates the first example of back gate voltage wires within a memory macro. The memory macro has an N-type well region N-well and a plurality of P-type well regions P-well provided therewithin. The memory macro has a memory cell array MCA having memory cells MC in four rows and five columns, a row-side peripheral circuit R-cir having four rows of word drivers WD, and a column-side peripheral circuit C-cir having five columns of column selection circuits CL.

Within the memory cell array MCA, six P-type well regions P-well (broken lines) extending in the column direction are provided, and the memory cells MC (dot-dash lines) in four rows and five columns each have P-type well regions P-well on both sides and an N-type well region N-well therebetween, with the NMOS transistors and PMOS transistors constituting the memory cells disposed.

Further, the row-side peripheral circuit R-cir has a P-type well region P-well (broken line) extending in the column direction and an N-type well region N-well, and within both well regions, NMOS transistors and PMOS transistors constituting word driver circuits are disposed.

The column-side peripheral circuit C-cir has a P-type well region P-well (broken line) extending in the row direction and an N-type well region N-well, and NMOS transistors and PMOS transistors (“T” in the figure) constituting column selection circuits are disposed.

The pitch (interval) of memory cells MC in the column direction and the pitch (interval) of word driver circuits WD in the column direction are identical. The pitch (interval) of memory cells MC in the row direction and the pitch (interval) of column selection circuits CL in the row direction are identical.

The back gate voltage lines Vbp, Vbn are laid out as follows. First, a well contact region 10 (gray in the figure) for disposition of a connection structure with the back gate voltage lines is provided in the memory cell array MCA, and on the well contact region 10 are disposed a line Vbn for the N-type back gate voltage Vbnwell and a line Vbp for the P-type back gate voltage Vbpwell; then, structures (black circles in the figure) for connection to the well regions N-well, P-well are disposed corresponding to the lines Vbn, Vbp.

In the row-side peripheral circuit R-cir also, a well contact region 12 is disposed at a position corresponding to the well contact region 10 between the word drivers WD. In the well contact region 12 also, a line Vbn for the N-type back gate voltage Vbnwell and a line Vbp for the P-type back gate voltage Vbpwell are disposed, and structures (black circles in the figure) for connection to the well regions N-well, P-well are disposed corresponding to the lines Vbn, Vbp.

That is, the two back gate voltage lines Vbp, Vbn are disposed within the well contact regions 10, 12, and contact structures (black circles) are disposed in the corresponding P-type well region P-well and N-type well region N-well. The back gate voltage lines Vbp, Vbn are for example at a negative voltage, and a voltage higher than the power supply voltage Vdd. Hence due to the problem of electrical crosstalk between lines, a comparatively sufficient distance is provided between these back gate voltage lines Vbp, Vbn and signal lines which change to the power supply voltage Vdd or ground Vss. Hence the height h1 of the well contact regions 10, 12 is set to approximately the same height as the memory cells MC or higher.

In FIG. 5, column selection circuits CL are disposed in the column-side peripheral circuit C-cir corresponding to each column of the memory cell array. In the example of FIG. 5, the pitch (interval) of memory cells in the row direction and the pitch (interval) of column selection circuits CL are the same, and the positions match. Consequently, the four lines comprising the bit line pair BL, BLx and the lines for the power supply voltage Vdd and for ground Vss, provided between the memory cells MC disposed in the column direction and the column selection circuits CL, can be made straight lines.

Further, in each of the regions of the column selection circuits CL are disposed, extending in the column direction, a line Vbp for the P-type back gate voltage Vbpwell and a line Vbn for the N-type back gate voltage Vbnwell, and contact structures for these.

By making the pitches of the regions of the column selection circuits CL and the regions of the memory cells identical, and providing a P-type back gate voltage line Vbp and N-type back gate voltage line Vbn for each column selection circuit CL, the column-direction structures become equal, and variable design of the word bit structure signifying the number of columns selected when one word line is selected is facilitated. This feature is particularly advantageous when SRAM memory macros which demand various word bit structures are embedded in system LSIs.

However, there are a number of problems with the layout example of FIG. 5. First, a P-type back gate voltage line Vbp and N-type back gate voltage line Vbn extending in a straight line in the column direction, and contact structures for these, are provided in each region of the column selection circuits CL. Consequently, the layout structure of the column selection circuits CL is constrained, that is governed, by the P-type back gate voltage line Vbp and N-type back gate voltage line Vbn and the contact structures for these, and the size h2 in the column direction tends to become large. Moreover, there may be circumstances in which there is little importance to provide, for each column, contact structures of the P-type back gate voltage lines Vbp and N-type back gate voltage lines Vbn to the corresponding well regions, and it is sufficient to provide contact structures for each of a plurality of columns. That is, there may be too many contact structures, which tend instead to waste area.

Second, as explained above, because lines Vbn for the N-type back gate voltage Vbnwell and lines Vbp for the P-type back gate voltage Vbpwell are disposed within the well contact region 10 in the memory cell array MCA, the column-direction size hl of the well contact region 10 becomes larger. This is because the N-type back gate voltage Vbnwell is at negative potential and the P-type back gate voltage Vbpwell is at a voltage higher than the power supply voltage Vdd, and consequently there is an importance to secure an adequate distance from other lines.

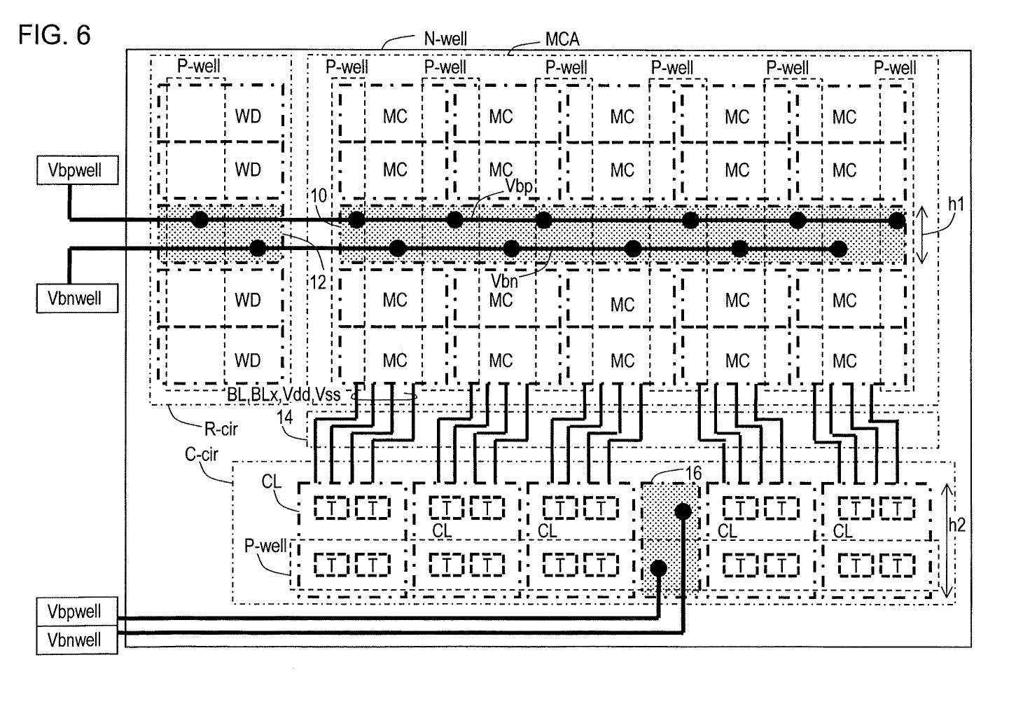

FIG. 6 illustrates a second example of back gate voltage lines in a memory macro. Similarly to the first example, this memory macro also has an N-type well region N-well and a plurality of P-type well regions P-well provided therewithin. The memory macro has a memory cell array MCA with memory cells MC in four rows and five columns, a row-side peripheral circuit R-cir having word drivers WD for four rows, and a column-side peripheral circuit C-cir having column selection circuits CL for five columns.

The structure of the memory cell array MCA and row-side peripheral circuit R-cir is the same as in the first example of FIG. 5. That is, a well contact region 10 extending in the row direction is provided within the memory cell array MCA, a well contact region 12 is also provided in the row-side peripheral circuit R-cir between word drivers WD, and in these well contact regions 10, 12, a line Vbn for the N-type back gate voltage Vbnwell, a line Vbp for the P-type back gate voltage Vbpwell, and contact structures for these are disposed.

The second example of FIG. 6 differs from the first example in that a line Vbn for the N-type back gate voltage Vbnwell, a line Vbp for the P-type back gate voltage Vbpwell, and contact structures for these are not disclosed in each of the regions of the column selection circuits CL in the column-direction peripheral circuit C-cir. Instead, a common well contact region 16 is provided in a central position of the plurality of column selection circuits CL, and these are disposed therein.

By this means, the layout of each of the column selection circuits CL is not constrained by back gate voltage wires, and so the area is reduced, and thus the column-direction size h2 of the column selection circuits CL is smaller than in the first example of FIG. 5. As explained above, disposing well contact structures in each column selection circuit is not a prerequisite, and so in the second example of FIG. 6 a common well contact region 16 is provided.

However, in the second example there is the following problem. First, by providing a well contact region 16 in common for the plurality of column selection circuits CL, the row-direction positions of the regions of the column selection circuits CL no longer correspond to the row-direction positions of memory cells MC in the memory cell array, and the four lines comprising the bit line pair BL, BLx and the lines of the power supply voltage Vdd and ground Vss, provided between the memory cells MC and the column selection circuits CL, is no longer laid out in a straight line in the column direction. As a result, a lateral-jog region 14 to shift the four lines once in the row direction is demanded. Because of this, the efforts made to reduce the column-direction size h2 of the column selection circuits CL are meaningless.

Second, similarly to the first example, a line Vbn for the N-type back gate voltage Vbnwell and a line Vbp for the P-type back gate voltage Vbpwell are disposed in the well contact region 10 in the memory cell array, so that the column-direction size hl of the well contact region 10 is increased.

### Example of Back Gate Voltage Lines within a Memory Macro in the Present Embodiment

Next, back gate voltage lines in a memory macro of the present embodiment, and the layout of well contact regions for these, with area efficiency improved compared with the above-described two examples, are explained.

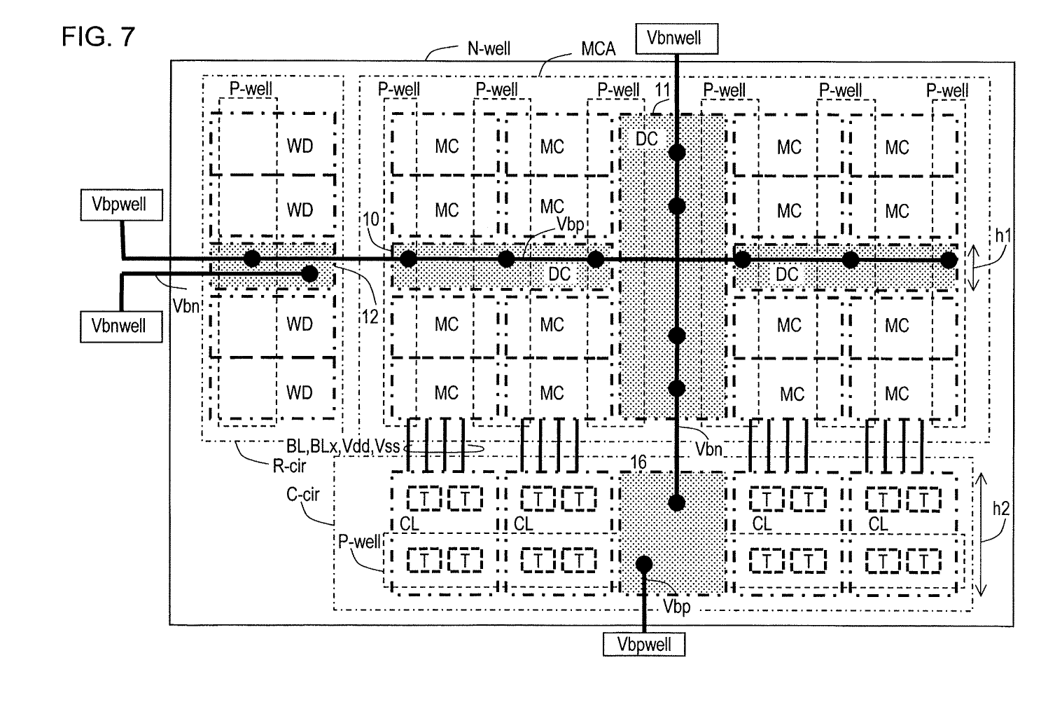

FIG. 7 illustrates back gate voltage lines in a memory macro of the embodiment. The N-type well region N-well in the memory macro, and the P-type well regions P-well therewithin, are the same as in FIG. 5 and FIG. 6.

Differences with the configuration of FIG. 5 and FIG. 6 are as follows. First, the memory cell array MCA has memory cells MC in four rows and four columns, and has therewithin a P-type well contact region 10 extending in the row direction and an N-type well contact region 11 extending in the column direction. Within the P-type well contact region 10 are disposed a line Vbp for the P-type back gate voltage Vbpwell and contact structures (black circles) thereof; within the N-type well contact region 11 are disposed a line Vbn for the N-type back gate voltage Vbnwell and contact structures (black circles) thereof. The contact structures (black circles) of the line Vbp for the P-type back gate voltage are disposed at each P-type well region P-well. The contact structures (black circles) of the line Vbn for the N-type back gate voltage are disposed at each row of memory cells. However, the contact structures (black circles) of the line Vbn for the N-type back gate voltage may be disposed at each of a plurality of rows.

The word driver circuits WD which are the row-side peripheral circuit R-cir have a column-direction pitch identical to that of the memory cells MC, and a well contact region 12 is provided between word driver circuits WD. This configuration is the same as in FIG. 5 and FIG. 6. Within the well contact region 12 are disposed in extension the line Vbp for the P-type back gate voltage in the P-type well contact region 10 in the memory cell array, and also the line Vbn for the N-type back gate voltage; also disposed are contact structures (black circles) for these.

The column selection circuits CL which are the column-side peripheral circuit C-cir are, similarly to FIG. 6, disposed at the same pitch as the memory cells MC, at positions corresponding to the memory cells MC. Further, a P-type back gate voltage line Vbp and N-type back gate voltage line Vbn are not provided within column selection circuits CL, and consequently four transistors T are disposed compactly. However, a well contact region 16 is disposed in common among a plurality of column selection circuits. And, an N-type back gate voltage line Vbn extending from the memory cell array side and contact structures (black circles) for this are disposed within the well contact region 16. Further, a P-type back gate voltage line Vbp and contact structures (black circles) for this are disposed. By means of such a configuration, the area of each column selection circuit CL is reduced, and the column-direction size h2 is made small similarly to FIG. 6.

By disposing the well contact region 16 among column selection circuits CL, and also disposing the N-type well contact region 11 extending in the column direction among memory cells in the memory cell array, the row-direction positions of the column selection circuits CL corresponding to the row-direction positions of the memory cells MC. As a result, the four lines comprising the bit line pairs BL, BLx and lines for the power supply voltage Vdd and ground Vss, disposed between the memory cells MC and the column selection circuits CL, are laid out in straight lines extending in the column direction, and a lateral-jog region 14 such as in FIG. 6 is not demanded.

Within the memory cell array MCA, by disposing the P-type well contact region 10 in the row direction and dividing the N-type well contact region 11 in the column direction individually, the P-type back gate voltage line Vbp is disposed within the P-type well contact region 10, and the N-type back gate voltage line Vbn is not so disposed within the P-type well contact region 10. By this means, the column-direction size hl of the P-type well contact region 10 is reduced.

Further, in the memory cell array MCA, the P-type well contact region 10 comprises a plurality of dummy cells DC having a configuration equivalent to the layout of the MOS transistors in the adjacent memory cells MC. Similarly, the N-type well contact region 11 comprises a plurality of dummy cells DC having a configuration equivalent to the layout of the MOS transistors in the adjacent memory cells MC. By this means, continuity of the configuration within the memory cell array is preserved, and shifts in position relative to the peripheral circuits are avoided.

The N-type back gate voltage lines Vbn supply the back gate voltage from voltage generation circuits Vbnwell provided within or outside the memory macro to the N-type well regions. Similarly, the P-type back gate voltage lines Vbp supply the back gate voltage from voltage generation circuits Vbpwell provided within or outside the memory macro to the P-type well regions.

These voltage generation circuits make the N-type back gate voltage Vbnwell higher than the power supply voltage Vdd and the P-type back gate voltage Vbpwell lower than ground Vss. Or, these voltage generation circuits control the N-type back gate voltage Vbnwell at a voltage equal to the power supply voltage Vdd or at a voltage higher than this, and control the P-type back gate voltage Vbpwell at a voltage equal to ground Vss or at a voltage lower than this.

By having the voltage generation circuits make the N-type back gate voltage Vbnwell higher than the power supply voltage Vdd and make the P-type back gate voltage Vbpwell lower than ground Vss, leakage currents in the off state of the PMOS transistors and NMOS transistors (off-leakage currents) is suppressed.

For example, when a memory macro is in the active state, the voltage generation circuits emphasize operation speed, controlling the N-type back gate voltage Vbnwell at a voltage equal to the power supply voltage Vdd and controlling the P-type back gate voltage Vbpwell at a voltage equal to ground Vss. When the memory macro is in the sleep state, the voltage generation circuits emphasize suppression of off-leakage currents, by controlling the N-type back gate voltage Vbnwell at a voltage higher than the power supply voltage Vdd and controlling the P-type back gate voltage Vbpwell at a negative voltage lower than ground Vss.

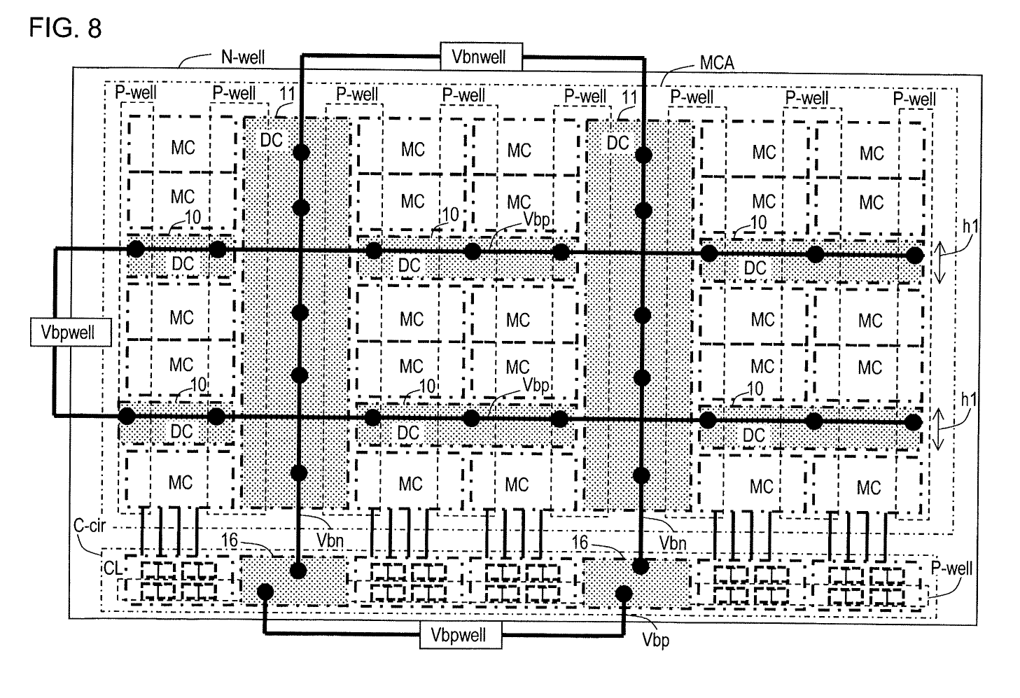

FIG. 8 illustrates another type of back gate voltage lines in a memory macro in this embodiment. The configuration of the N-type well region N-well and the P-type well regions P-well formed therewithin are the same as in FIG. 7. A memory cell array MCA and column-side peripheral circuit C-cir are disposed. In FIG. 8, the row-side peripheral circuit R-cir is omitted, but is disposed similarly to FIG. 7.

The configuration differs from that of FIG. 7 as follows. First, the memory cell array MCA has memory cells MC in five rows and five columns, and has thereamong two P-type well contact regions 10 extending in the row direction and two N-type well contact regions 11 extending in the column direction.

Corresponding to this, five rows of column selection circuits CL of the column-side peripheral circuit are also disposed, and two well contact regions 16 are disposed thereamong, at positions corresponding to the two N-type well contact regions 11.

In this way, as the data capacity of a memory macro is increased, the number of memory cells within the memory cell array MCA corresponding thereto increases, and the number of well contact regions 10, 11 also increases.

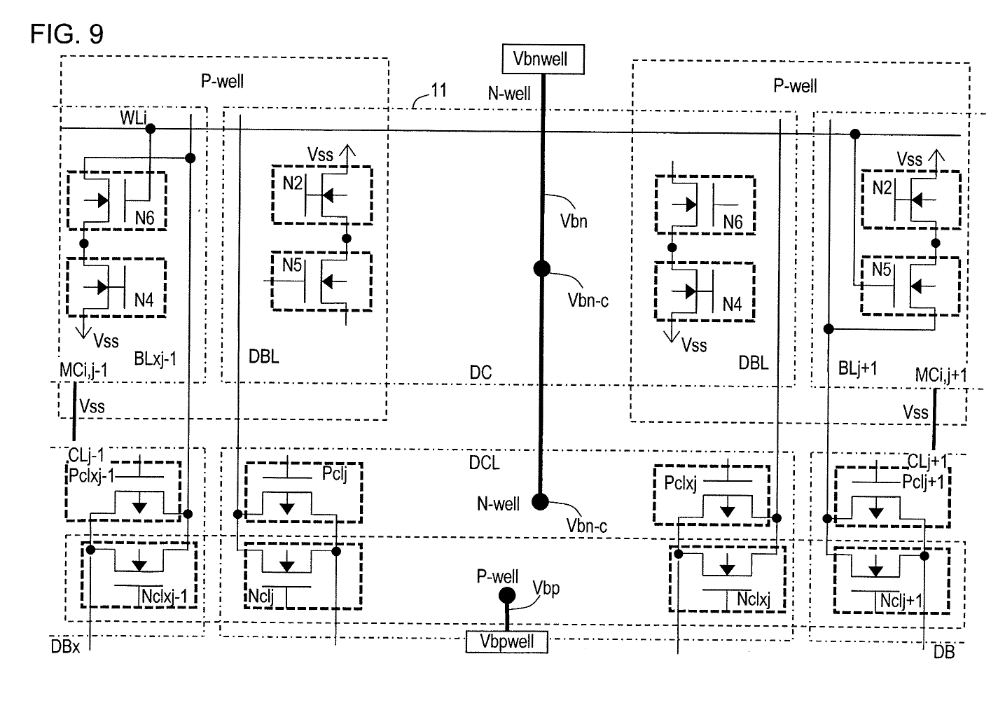

FIG. 9 illustrates the configuration of dummy cells DC comprised by an N-type well contact region 11. The dummy cells DC differ from the memory cells MCi,j of FIG. 4 in not having PMOS transistors P1, P3 or connection wires for these in the N-type well region N-well of the memory cell MCi,j, but having NMOS transistors N2, N5 and N6, N4 disposed on both sides within the P-type well region P-well. In the N-type well region N-well in which PMOS transistors P1, P3 had been disposed, a structure Vbn-c for contact of the N-type back gate voltage line Vbn and the N-type well region N-well is disposed.

In this way, the dummy cell DC has NMOS transistors N2, N5 adjacent to the NMOS transistors N6, N4 of the left-adjacent memory cell MCi,j−1, and has NMOS transistors N6, N4 adjacent to the NMOS transistors N2, N5 of the right-adjacent memory cell MCi,j+1. Hence the layout configuration of the dummy cell DC preserves the continuity of the layout configuration of the memory cells MCi,j−1, MCi,j+1 adjacent on both sides.

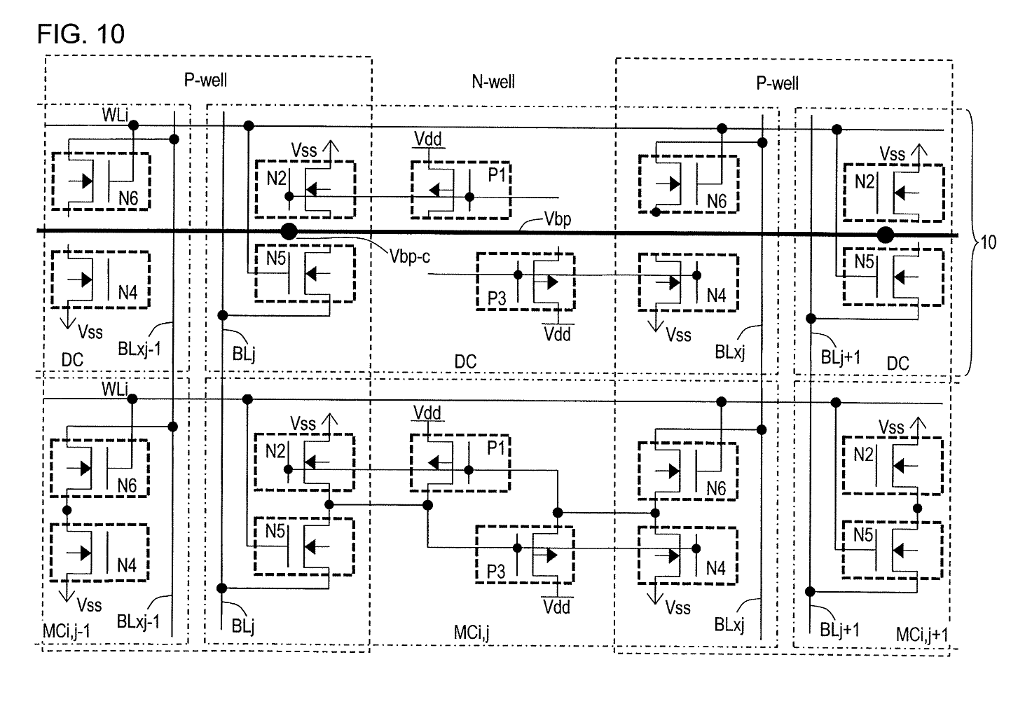

FIG. 10 illustrates the configuration of dummy cells DC comprised by the P-type well contact regions 10. The dummy cells DC in the P-type well contact regions 10 are enclosed between vertically adjacent ordinary memory cells MCi,j and MCi−1,j (not illustrated).

The dummy cells DC differ from the memory cell MCi,j of FIG. 4 in not having column-direction wires connecting the six transistors P1, N2, P3, N4, N5, N6. However, three transistors of the six transistors are disposed so as to be somewhat spread out in the vertical directions.

Further, the P-type back gate voltage line Vbp disposed along the P-type well contact regions 10 is provided between the groups of three transistors spread out in the vertical directions. The P-type back gate voltage line Vbp is connected to the P-type well region P-well via the contact structure Vbp-c.

The three transistors N5, P3, N4 on the lower side in the dummy cell DC in the P-type well contact region 10 are disposed near the transistors N2, P1, N6 in the adjacent memory cell MCi,j. Hence the continuity of the transistor structure in the column direction is maintained. The upper-side three transistors N2, P1, N6 are also disposed near three transistors in the memory cell adjacent on the upper side, which is not illustrated.

As explained above, in the semiconductor device of this embodiment, within the memory cell array are provided P-type well contact regions 10 extending in the row direction within which are disposed P-type back gate voltage lines Vbp extending in the row direction, and N-type well contact regions 11 extending in the column direction within which are disposed N-type back gate voltage lines Vbn extending in the column direction. Further, in the column-side peripheral circuit are provided well contact regions 16 at positions corresponding to the N-type well contact regions 11, and therein are disposed N-type back gate voltage lines Vbn and P-type back gate voltage lines Vbp extending from the memory cell array in the column direction. By this means, the layout efficiency can be raised and the memory macro area can be reduced.

Further, a memory macro is easily configured with memory cell arrays corresponding to different data capacities, and design of memory macros for embedding in a system LSI is facilitated.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

1. A semiconductor memory device, comprising:
a memory cell array in which are disposed a plurality of memory cells, each including a first conduction type transistor and a second conduction type transistor;
a plurality of column-side peripheral circuits which are disposed with the same row-direction interval as the memory cells, and which are disposed corresponding to a group of column-direction memory cells disposed in the column direction;
a first conduction type well region which is formed within the memory cell array, and in which are formed the second conduction type transistors of the plurality of memory cells;
a second conduction type well region which is formed within the first conduction type well region and is disposed separately in the row direction, and in which are formed the first conduction type transistors of the plurality of memory cells;
a second conduction type well contact region which is disposed extending in the row direction among the plurality of memory cells, and which is provided in the plurality of second conduction type well regions;
a first conduction type well contact region which is disposed extending in the column direction among the plurality of memory cells, and provided in the first conduction type well region;
a column-side peripheral contact region, which is disposed among the plurality of column-side peripheral circuits, and disposed at a position corresponding to the first conduction type well contact region, and moreover provided in the first conduction type well region and the second conduction type well regions;
a first conduction type back gate voltage line, which connects to the first conduction type well region within the first conduction type well contact region; and
a second conduction type back gate voltage line, which connects to the second conduction type well region within the second conduction type well contact region.

2. The semiconductor memory device according to claim 1, wherein the first conduction type back gate voltage line is disposed extending along the first conduction type well contact region and connected to the first conduction type well region within the column-side peripheral contact region, and
the second conduction type back gate voltage line is disposed extending along the second conduction type well contact region.

3. The semiconductor memory device according to claim 2, further comprising a second conduction type column-side peripheral back gate voltage line, connected to the second conduction type well region within the column-side peripheral contact region.

4. The semiconductor memory device according to claim 1, wherein
the first conduction type well contact region includes a plurality of first dummy cell regions disposed in the column direction, and
the first dummy cell regions are disposed at the same column-direction interval as the memory cells, and include at least a portion of the transistors in the memory cells.

5. The semiconductor memory device according to claim 4, wherein
the second conduction type well contact region includes a plurality of second dummy cell regions disposed in the row direction, and
the second dummy cell regions are disposed at the same row-direction interval as the memory cells, and include at least a portion of the transistors in the memory cells.

6. The semiconductor memory device according to claim 1, wherein
the source region of the first conduction type transistors in the memory cells is connected to a first power supply line to which a first power supply voltage is applied,
the source region of the second conduction type transistors is connected to a second power supply line to which a second power supply voltage higher than the first power supply voltage is applied,
the first conduction type back gate voltage line is at a potential higher than the second power supply voltage, and
the second conduction type back gate voltage line is at a potential lower than the first power supply voltage.

7. The semiconductor memory device according to claim 5, wherein
the memory cell array includes a plurality of word lines extending in the row direction and a plurality of bit lines extending in the column direction, and
the memory cells each include one pair of CMOS inverters having cross-connected inputs and outputs and disposed between the power supply line and the ground line, and also include one pair of first conduction type transmission transistors, respectively provided between output terminals of the pair of CMOS inverters and the bit line pair, and controlled by the word line for conduction and non-conduction.

8. The semiconductor memory device according to claim 7, wherein the bit line pairs are disposed in a straight manner between the column-direction memory cell group and the column-side peripheral circuit corresponding thereto.

9. The semiconductor memory device according to claim 1, wherein the first conduction type well region is formed more deeply than the second conduction type well regions, and the first conduction type well region disposed among the second conduction type well region is contiguous.
